(19) United States
(12) Patent Application Publication
(10) Pub. No.: US 2017/0012081 A1
(43) Pub. Date: Jan. 12, 2017

(54) CHIP PACKAGE AND MANUFACTURING METHOD THEREOF

(71) Applicant: XINTEC INC., Taoyuan City (TW)

(72) Inventors: Chia-Lun SHEN, Taoyuan City (TW); Yi-Ming CHANG, Taoyuan City (TW); Hsiao-Lan YEH, Tainan City (TW); Yen-Shih HO, Kaohsiung City (TW)

(21) Appl. No.: 15/181,288

(22) Filed: Jun. 13, 2016

Related U.S. Application Data
(60) Provisional application No. 62/189,120, filed on Jul. 6, 2015.

(51) Int. Cl. H01L 27/146; H01L 21/78; H01L 25/065; H01L 23/00

(52) U.S. Cl. CPC H01L 27/14687; H01L 24/03; H01L 24/14; H01L 24/06; H01L 24/13; H01L 24/17; H01L 24/16; H01L 24/81; H01L 24/94; H01L 21/78; H01L 27/14636; H01L 25/0657; H01L 2224/0331; H01L 2224/1132; H01L 2224/1403; H01L 2224/0603; H01L 2224/13016; H01L 2224/1703; H01L 2224/16057; H01L 2224/0401; H01L 2224/06135; H01L 2224/06131; H01L 2224/11849; H01L 2224/1181; H01L 2224/17135; H01L 2224/16225; H01L 2224/81191; H01L 2224/818; H01L 2224/81011; H01L 2225/06513; H01L 2225/06517; H01L 2225/06524; H01L 2225/06568

(57) ABSTRACT

A manufacturing method of a chip package includes the following steps. A patterned solder paste layer is printed on a patterned conductive layer of a wafer. Plural solder balls are disposed on the solder paste layer that is on a first portion of the conductive layer. A reflow process is performed on the solder balls and the solder paste layer. A flux layer converted from a surface of the solder paste layer is cleaned.

### RELATED APPLICATIONS

This application claims priority to US provisional Application Serial Number 62/189,120, filed Jul. 6, 2015, which is herein incorporated by reference.

### BACKGROUND

Field of Invention

The present invention relates to a chip package and a manufacturing method of the chip package.

Description of Related Art

A typical semiconductor chip has a back surface with a conductive layer on which plural solder balls that are disposed for electrically connecting plural contacts of a printed circuit board. In general, the sizes of the solder balls on a same chip are identical. Hence, after the chip is assembled to the printed circuit board, the front surface of the chip (i.e., an image sensing surface) presents a horizontal state. When the image sensing surface detects an image, the collection of light is therefore limited and the image quality is difficult to be improved.

At the present, there are several methods to form solder balls that have different sizes on one chip. Firstly, two stencils having three dimensional structures are used in a solder paste printer. One of the stencils is used to print smaller solder balls, and the other is used to print larger solder balls. The smaller solder balls are formed by printing solder paste one time, and the larger solder balls are formed by printing the solder paste two times. In other words, the solder balls having different sizes are formed due to different thicknesses of the solder pastes. Secondly, a solder paste printer is used to form larger solder balls, and a solder dispenser is used to form smaller solder balls. Thirdly, a solder mask layer having different sizes of openings and a stencil that has different sizes of openings are designed, such that solder balls having different sizes can be formed after solder paste is printed on a conductive layer that is in the openings of the solder mask layer.

However, typical manufacturing methods of solder balls that have different sizes need to utilize two kinds of stencils or two kinds of process apparatuses, which is hard to reduce the manufacturing cost. Moreover, a distance between two adjacent solder balls is larger than 400 μm due to process limitations. If the distance is smaller than 400 μm, the solder balls may have a short circuit because of increasing the possibility of bridge. On the other hand, if the distance is larger than 400 μm, it becomes an inconvenient factor for chip miniaturization.

### SUMMARY

An aspect of the present invention is to provide a manufacturing method of a chip package.

According to an embodiment of the present invention, a manufacturing method of a chip package includes the following steps. A patterned solder paste layer is printed on a patterned conductive layer of a wafer. A plurality of solder balls are disposed on the solder paste layer that is on a first portion of the conductive layer. A reflow process is performed on the solder balls and the solder paste layer. A flux layer that is converted from a surface of the solder paste layer is cleaned.

Another aspect of the present invention is to provide a chip package.

According to an embodiment of the present invention, a chip package includes a first chip, a patterned solder paste layer, and a plurality of solder balls. A surface of the first chip has a patterned conductive layer. The patterned solder paste layer is located on the conductive layer. The solder balls are located on the solder paste layer that is on a first portion of the conductive layer. No solder ball is located on the solder paste layer that is on a second portion of the conductive layer. After a reflow process, the solder balls and the solder paste layer that is on the first portion of the conductive layer form a plurality of first conductive balls, and the solder paste layer on the second portion of the conductive layer forms a plurality of second conductive balls.

In the aforementioned embodiment of the present invention, since the solder paste layer is printed on the entire conductive layer and thereafter the solder balls are disposed on the solder paste layer that is on the first portion of the conductive layer, the second portion of the conductive layer has the solder paste layer thereon but has no solder ball thereon. The solder paste layer is made of a material including tin and flux. After the reflow process, tin may be solidified and centralized, such that the solder balls and the solder paste layer that is on the first portion of the conductive layer form the first conductive balls that have a large size, and the solder paste layer on the second portion of the conductive layer forms the second conductive balls that have a small size. In other words, the conductive balls having different sizes are formed through the material property of solder paste and through selecting positions for disposing the solder balls in the manufacturing method of the chip package of the present invention.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a flow chart of a manufacturing method of a chip package according to one embodiment of the present invention;

FIG. 2 is a cross-sectional view of a solder paste layer after being printed on a conductive layer of a wafer according to one embodiment of the present invention;

FIG. 3 is a cross-sectional view of solder balls after being disposed on the solder paste layer that is on a portion of the conductive layer shown in FIG. 2;

FIG. 4 is a cross-sectional view of the structure shown in FIG. 3 after a reflow process and being cleaned;

FIG. 5 is a cross-sectional view of a chip package according to one embodiment of the present invention;

FIG. 6 is a bottom view of the chip package shown in FIG. 5;

FIG. 7 is a cross-sectional view of the chip package shown in FIG. 5 after being assembled to a printed circuit board; and

FIG. 8 is a cross-sectional view of a chip package according to one embodiment of the present invention after being assembled to a printed circuit board.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

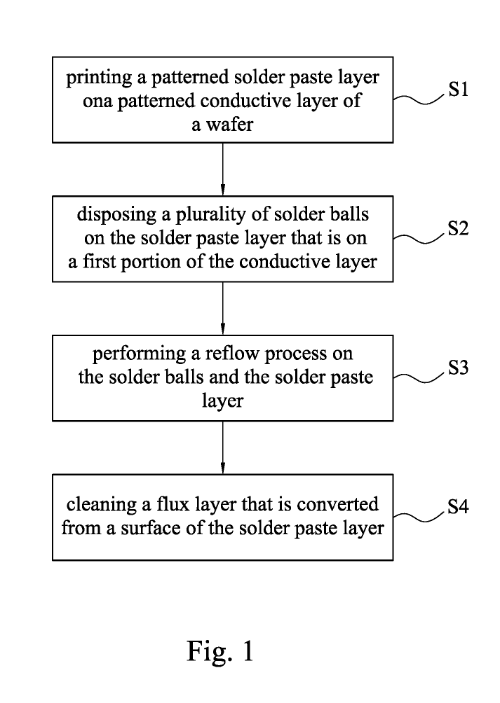

FIG. 1 is a flow chart of a manufacturing method of a chip package according to one embodiment of the present invention. The manufacturing method of the chip package includes the following steps. In step S1, a patterned solder paste layer is printed on a patterned conductive layer of a wafer. Thereafter, in step S2, a plurality of solder balls are disposed on the solder paste layer that is on a first portion of the conductive layer. Afterwards, in step S3, a reflow process is performed on the solder balls and the solder paste layer. Subsequently, in step S4, a flux layer that is converted from a surface of the solder paste layer is cleaned.

In the following description, the aforesaid steps in the manufacturing method will be explained.

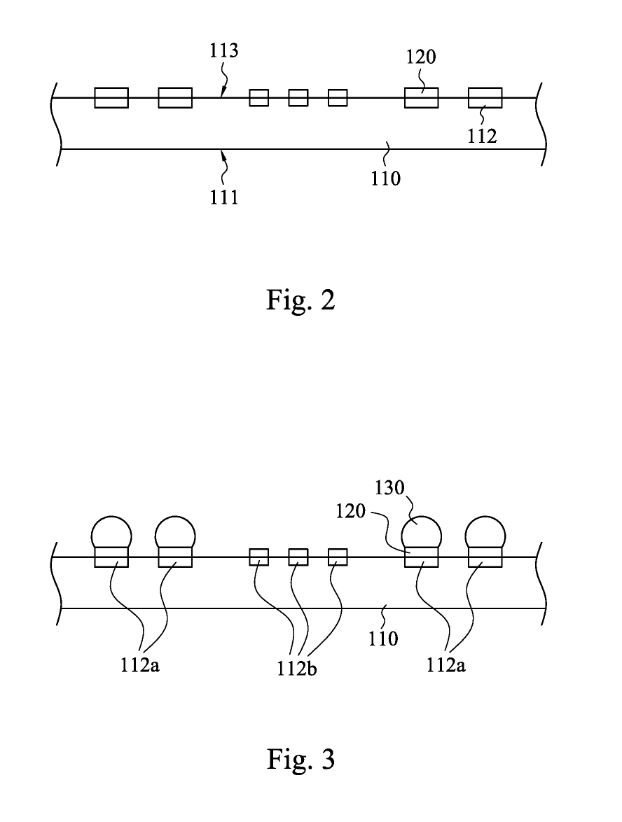

FIG. 2 is a cross-sectional view of a solder paste layer 120 after being printed on a conductive layer 112 of a wafer 110 according to one embodiment of the present invention. The wafer 110 has a front surface 111 and a back surface 113. The front surface 111 of the wafer 110 is an image sensing surface that is capable of detecting light. The back surface 113 of the wafer 110 has the patterned conductive layer 112. The patterned solder paste layer 120 may be printed on the conductive layer 112 of the wafer 110 by a printer.

FIG. 3 is a cross-sectional view of solder balls 130 after being disposed on the solder paste layer 120 that is on a portion of the conductive layer 112 shown in FIG. 2. As shown in FIG. 2 and FIG. 3, after the solder paste layer 120 is printed on the conductive layer 112, the solder balls 130 may be disposed on the solder paste layer 120 that is on a first portion of the conductive layer 112a by a printer, while a second portion of the conductive layer 112b has the solder paste layer 120 thereon but has no solder ball 130 thereon. In this step, a stencil having a plurality of openings may be assembled in the printer, such that the openings of the stencil are respectively aligned with the solder paste layer 120 that is on the first portion of the conductive layer 112a. Thereafter, the solder balls 130 are placed on the stencil to respectively roll into the openings of the stencil, such that the solder balls 130 are located on the solder paste layer 120 that is on the first portion of the conductive layer 112a. In this embodiment, the openings of the stencil are formed by electroforming. Hence, the openings of the stencil may have high precision.

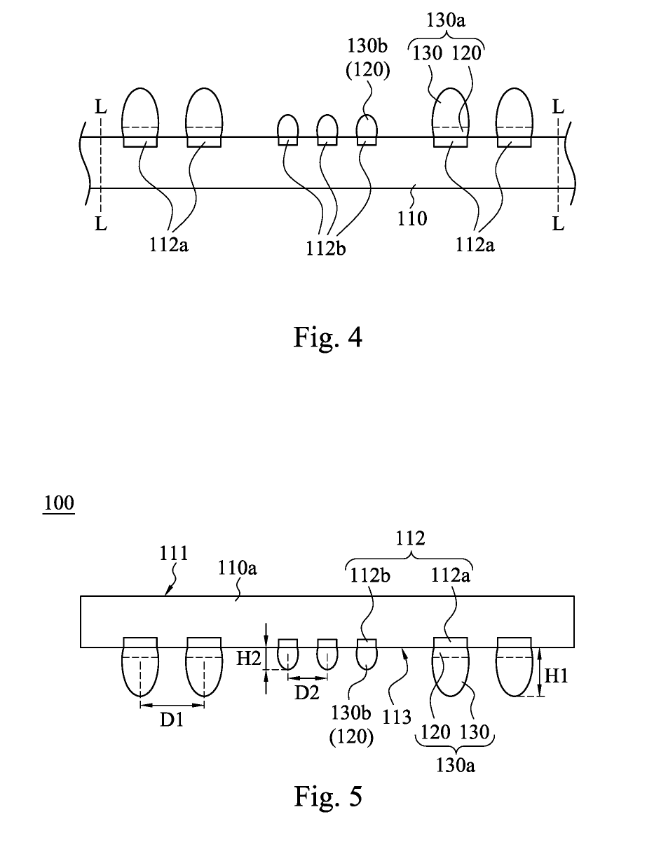

FIG. 4 is a cross-sectional view of the structure shown in FIG. 3 after a reflow process and being cleaned. As shown in FIG. 3 and FIG. 4, after the solder balls 130 are disposed on the solder paste layer 120 that is on the first portion of the conductive layer 112a, a reflow process may be performed on the solder balls 130 and the solder paste layer 120. For example, the structure of FIG. 3 is placed in an infrared reflow furnace, such that the solder balls 130 and the solder paste layer 120 are located in a high-temperature environment (e.g., 240° C.). The solder paste layer 120 is made of a material including tin and flux. After the reflow process, tin of the solder paste layer 120 may be solidified and centralized due to its physical properties, and the surface of the solder paste layer 120 is converted to a flux layer.

As a result, the solder balls 130 and the solder paste layer 120 that is on the first portion of the conductive layer 112a may form first conductive balls 130a that have larger sizes, and the solder paste layer 120 on the second portion of the conductive layer 112b may form second conductive balls 130b that have smaller sizes.

After the first conductive balls 130a and the second conductive balls 130b are formed, the flux layer converted from the surface of the solder paste layer 120 may be cleaned. For example, water may be used to clean the flux layer. Thereafter, the wafer 110 may be cut along line L-L to form the chip package 100 of FIG. 5.

In the manufacturing method of the chip package of the present invention, since the solder paste layer 120 is printed on the entire conductive layer 112 (see FIG. 2) and thereafter the solder balls 130 are disposed on the solder paste layer 120 that is on the first portion of the conductive layer 112a, the second portion of the conductive layer 112b has the solder paste layer 120 thereon but has no solder ball 130 thereon. One stencil and one apparatus (i.e., a printer) are used to accomplish the two steps, thereby reducing the manufacturing cost.

In addition, the solder paste layer 120 is made of a material including tin and flux. After a reflow process, tin may be solidified and centralized, such that the solder balls 130 and the solder paste layer 120 that is on the first portion of the conductive layer 112a may form the first conductive balls 130a that have a large size, and the solder paste layer 120 on the second portion of the conductive layer 112b may form the second conductive balls 130b that have a small size. In other words, the first and second conductive balls 130a, 130b having different sizes are formed through the material property of the solder paste layer 120 and through selecting positions for disposing the solder balls 130 in the manufacturing method of the chip package of the present invention.

It is to be noted that the connection relationships and the materials of the elements described above will not be repeated in the following description. In the following description, the structure and application of the chip package will be described.

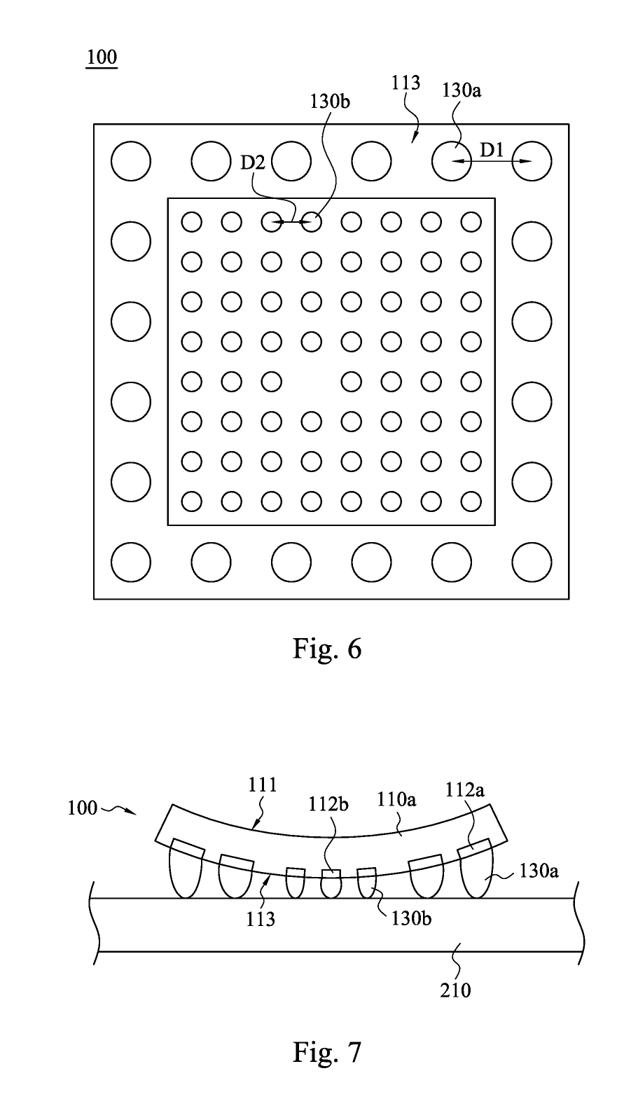

FIG. 5 is a cross-sectional view of a chip package 100 according to one embodiment of the present invention. FIG. 6 is a bottom view of the chip package 100 shown in FIG. 5. As shown in FIG. 5 and FIG. 6, the chip package 100 includes a chip 110a, the solder paste layer 120, and the solder balls 130. The chip 110a may be referred to as one of plural chips that are formed by cutting the wafer 110 of FIG. 4. The front surface 111 of the chip 110a is an image sensing surface, and the back surface 113 of the chip 110a has the patterned conductive layer 112. The patterned solder paste layer 120 is located on the conductive layer 112. The solder balls 130 are located on the solder paste layer 120 that is on the first portion of the conductive layer 112a. No solder ball 130 is located on the solder paste layer 120 that is on the second portion of the conductive layer 112b. After a reflow process, the solder balls 130 and the solder paste layer 120 that is on the first portion of the conductive layer form the first conductive balls 130 that have larger sizes, and the solder paste layer 120 on the second portion of the conductive layer 112b forms the second conductive balls 130b that have smaller sizes. The first conductive balls 130a surround the second conductive balls 130b.

In the chip package 100 formed through the manufacturing method of the present invention, the two centers of the two adjacent first conductive balls 130a may be separated at a distance D1 from 550 μm to 600 μm, and the two centers of the two adjacent second conductive balls 130b may be separated at a distance D2 from 200 μm to 250 μm. The two adjacent first conductive balls 130a and the two adjacent second conductive balls 130b of the chip package 100 do not easily form a short circuit caused by bridge, which is a convenient factor for the requirements of chip miniaturization.

Moreover, the height H1 of each of the first conductive balls 130a may be in a range from 300 μm to 400 μm, and the height H2 of each of the second conductive balls 130b is in a range from 10 μm to 100 μm. Therefore, a height difference is formed between the first and second conductive balls 130a, 130b. The height difference may be utilized to change the shape of the chip package 100, such as the chip package 100 shown in FIG. 7.

FIG. 7 is a cross-sectional view of the chip package 100 shown in FIG. 5 after being assembled to a printed circuit board 210. As shown in FIG. 7, the chip package 100 is disposed on the printed circuit board 210, such that the back surface 113 of the chip 110a is subject to supporting forces of the first and second conductive balls 130a, 130b so as to be a curved surface. The first conductive balls 130a are located on the edge region of the curved surface, and the second conductive balls 130b are located on the central region of the curved surface. Since the chip package 100 has the first conductive balls 130a that have larger sizes and the second conductive balls 130b that have smaller sizes, the chip 110a may be bent to enable the front surface 111 to be present a concave surface after the first and second conductive balls 130a, 130b on the back surface 113 of the chip 110a are electrically connected to the contacts of the printed circuit board 210. As a result, when the image sensing surface of the chip package 100 (i.e., the front surface 111 of the chip 110a) detects light, much light may be collected to further improve the image quality of the chip package 100.

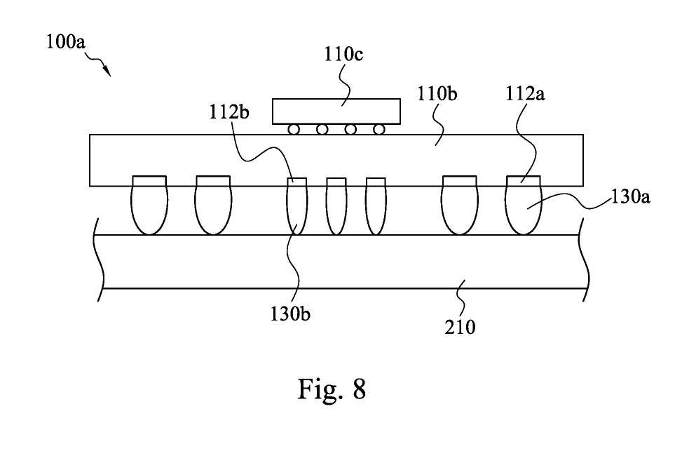

FIG. 8 is a cross-sectional view of a chip package 100a according to one embodiment of the present invention after being assembled to the printed circuit board 210. The difference between this embodiment and the embodiment shown in FIG. 7 is that the first and second conductive balls 130a, 130b of the chip package 100a have the same height, so that the chip 110b of the chip package 100a is not bent and is substantially parallel to the printed circuit board 210. Furthermore, the chip package 100a may further have a chip 110c that is stacked on the chip 110b to provide a specific function. The chip 110c is corresponding to the second conductive balls 130b in position. In other words, the chip 110c is above the second conductive balls 130b.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A manufacturing method of a chip package, the manufacturing method comprising:
(a) printing a patterned solder paste layer on a patterned conductive layer of a wafer;
(b) disposing a plurality of solder balls on the solder paste layer that is on a first portion of the conductive layer;
(c) performing a reflow process on the solder balls and the solder paste layer; and
(d) cleaning a flux layer that is converted from a surface of the solder paste layer.

2. The manufacturing method of claim 1, wherein step (a) and step (b) are performed in a printer.

3. The manufacturing method of claim 2, wherein step (b) comprises:
assembling a stencil having a plurality of openings in the printer, wherein the openings are aligned with the solder paste layer that is on the first portion of the conductive layer.

4. The manufacturing method of claim 3, wherein step (b) further comprises:
placing the solder balls on the stencil to respectively roll into the openings of the stencil, such that the solder balls are located on the solder paste layer that is on the first portion of the conductive layer.

5. The manufacturing method of claim 3, wherein the openings of the stencil are formed by electroforming.

6. The manufacturing method of claim 1, wherein the solder balls and the solder paste layer that is on the first portion of the conductive layer form a plurality of conductive balls after step (c), and two centers of the two adjacent conductive balls are separated at a distance from 550 μm to 600 μm.

7. The manufacturing method of claim 6, wherein a height of each of the conductive balls is in a range from 300 μm to 400 μm.

8. The manufacturing method of claim 1, wherein no solder ball is located on a second portion of the conductive layer, and the solder paste layer on the second portion of the conductive layer forms a plurality of conductive balls after step (c), and two centers of the two adjacent conductive balls are separated at a distance from 200 μm to 250 μm.

9. The manufacturing method of claim 8, wherein a height of each of the conductive balls is in a range from 10 μm to 100 μm.

10. The manufacturing method of claim 1, wherein step (c) are performed in an infrared reflow furnace.

11. The manufacturing method of claim 1, further comprising:
cutting the wafer to form the chip package.

12. A chip package, comprising:
a first chip, wherein a surface of the first chip has a patterned conductive layer;
a patterned solder paste layer located on the conductive layer; and
a plurality of solder balls located on the solder paste layer that is on a first portion of the conductive layer, wherein no solder ball is located on the solder paste layer that is on a second portion of the conductive layer; after a reflow process, the solder balls and the solder paste layer that is on the first portion of the conductive layer form a plurality of first conductive balls, and the solder paste layer on the second portion of the conductive layer forms a plurality of second conductive balls.

13. The chip package of claim 12, wherein two centers of the two adjacent first conductive balls are separated at a distance from 550 μm to 600 μm.

14. The chip package of claim 12, wherein a height of each of the first conductive balls is in a range from 300 μm to 400 μm.

15. The chip package of claim 12, wherein two centers of the two adjacent second conductive balls are separated at a distance from 200 μm to 250 μm.

16. The chip package of claim 12, wherein a height of each of the second conductive balls is in a range from 10 μm to 100 μm.

17. The chip package of claim 12, wherein the first conductive balls surround the second conductive balls.

18. The chip package of claim 12, wherein the chip package is disposed on a printed circuit board, such that the surface of the first chip is subject to supporting forces of the first and second conductive balls so as to be a curved surface, wherein the first conductive balls are located on an edge region of the curved surface, and the second conductive balls are located on a central region of the curved surface.

19. The chip package of claim 12, further comprising:
a second chip stacked on the first chip and corresponding to the second conductive balls in position.
